(19) United States
(12) Patent Application Publication
(10) Pub. No.: US 2021/0082884 A1
(43) Pub. Date: Mar. 18, 2021

(54) DISPLAY ELEMENT, DISPLAY DEVICE AND METHOD FOR PRODUCING A CONTACT STRUCTURE IN A PLURALITY OF DISPLAY ELEMENTS

(71) Applicant: OSRAM OLED GmbH, Regensburg (DE)

(72) Inventor: Thomas SCHWARZ, Regensburg (DE)

(21) Appl. No.: 16/955,552

(22) PCT Filed: Jan. 16, 2019
(86) PCT No.: PCT/EP2019/051068

§ 371 Date: Jun. 18, 2020

(30) Foreign Application Priority Data
Jan. 18, 2018 (DE) 10 2018 101 090.7

(51) Int. Cl. H01L 25/075; H01L 25/16; H01L 23/00

(52) U.S. Cl. CPC H01L 25/0753; H01L 25/167; H01L 24/32; H01L 24/03; G09G 3/32; H01L 25/162; G09G 2300/026; G09G 2300/0452; H01L 24/05

(57) ABSTRACT

A display element for a video wall having a plurality of light-emitting components on a carrier, which has a front side, a rear side and an edge side running between the front and rear sides. The circuit structures are arranged on the front side and the rear side and are electrically conductively connected to one another via a contact structure arranged on the edge side. The edge side is embodied in a scored, broken, ground, polished, melted, sawn, chamfered, rounded or notched way.

The invention relates to a display element for a video wall, to a display device with a plurality of display elements and a method for producing a contact structure in a plurality of display elements.

This patent application claims the priority of the German patent application 102018101090.7, the disclosure content of which is hereby incorporated by reference.

A video wall is a large display area for displaying moving pictures, such as those used at sports events or concerts. Such a video wall is usually set up in a modular way with a number of display elements, also called video wall modules. They can have a display area of several or even many square meters.

Conventional active-matrix display devices or screens have a part of the column and row electronics for driving the pixels in TFT technology on a glass substrate on the display field or display panel. The electronics are located at the edge of the panel. This also applies to electrical connection areas. Glass substrates are processed for the TFTs in ever larger panels. Panels measuring 2.9 m×3.4 m are conceivable. The area costs of the panels are low (approx. 500 €/m2) and the structural sizes are small (approx. 3 μm line width).

In order not to impair the display, it is desirable to join display elements, if possible, without visual impairment by a visible edge or visible seam. In other words: In order to be able to join display elements seamlessly together, borderless display elements are desirable.

This is made possible by a display element for a video wall with a plurality of light-emitting components on a carrier. The carrier has a front side, a rear side and an edge side running between the front and rear sides, wherein circuit structures are arranged on the front side and the rear side and are electrically conductively connected to one another via a contact structure arranged on the edge side.

The carrier is advantageously a planar glass substrate with parallel front and rear sides. The edge side is commonly also called the rim or edge.

The circuit structures are embodied as structured front and rear side metallizations. The contact structure is a structured metallization, which is either only arranged on the edge side or extends beyond it on the front and/or rear side. It has one or more contact regions. The contact structure connects the front and rear side metallizations by extending to edge side regions of the front and rear side metallization and thus creates an electrically conductive connection.

The light-emitting components advantageously comprise light-emitting diodes, or LEDs for short, which emit light in the colours red, green and blue.

The contact structure has the same function as a via through the carrier or panel. However, it is placed at the outer edge, which has the following advantages: no hole drilling process is required and it requires little effort, since the separation technology has to be carried out anyway. No multi-stage hole drilling process is required to achieve small contact diameters. No large area metallization is necessary for hole filling, because only the edge side is metallized.

The display element comprises in one configuration a plurality of pixels arranged in rows and columns, wherein one or more chips emitting red, green and blue are arranged in each pixel. A pixel may contain one chip with red, green and blue LEDs or one red, one green and one blue LED chip. The LED chips do not need to be positioned centrally in the pixel. An off-centre arrangement creates space for the contact on the edge.

In one embodiment, the circuit structures comprise row and column conductor tracks and a drive circuit or parts of a drive circuit for selectively driving the components. The row and column conductor tracks allow for selectively driving the pixels.

The contact structure comprises a plurality of electrically conductive contact regions, which each connect a region of the circuit structure on the front side extending to the edge side with a region of the circuit structure on the rear side extending to the edge side. The contact region comprises edges running from the front side to the rear side, which edges are parallel, concave or convex to one another. Between two adjacent contact regions, a region of electrically insulating material may be arranged on the edge side to prevent short circuits between the contact regions.

In one embodiment, the carrier has a rectangular basic shape with opposite first edge side regions and opposite second edge side regions running perpendicularly to the first edge side regions. The contact structures may be arranged on only one of the first and second edge side regions, which is easy to produce as the edge side metallization is arranged on only one edge side region. In this way, row or column conductor tracks are connected to the contact structure on only one edge side region. Alternatively, the edge side metallization can be applied to two edge side regions. The contact structures can be arranged on each one of the first and second edge side regions, so that row and column conductor tracks are in each case connected to the contact structure only on one edge side region. The contact structures can be arranged only on either the first edge side regions or only on the second edge side regions, so that either the row or the column conductor tracks are connected to the contact structure on two opposite edge side regions. The contact structures can be arranged on three of the first and the second edge side regions. The contact structures can be arranged on all edge side regions, which means on both the first and second edge side regions, so that both the row and the column conductor tracks are connected to the contact structure on both sides.

In one embodiment, the circuit structure comprises on the front side and/or on the rear side several conductive, preferably metallic, structure layers arranged one above the other, at least one of which is connected to the contact structure. An insulating layer, also known as passivation, is arranged between adjacent conductive structure layers. The front and rear side metallization thus comprise one or more structured, electrically conductive, semi-conductive and/or non-conductive layers.

The edge side can be embodied in a scored or broken way, which makes it easy to produce. The edge side can be embodied in a ground, polished, melted, sawn (by side grinding) way. The edge side may be chamfered, rounded or notched, which is associated with improved mechanical properties. In the case of notched edge sides, the front and rear side metallization extend into the notched edge side region, and the contact structure does not cover the front and rear side.

A display device comprises a plurality of the display elements described above, which are preferably arranged in a lateral plane so that at least one contact region of the contact structure of one display element is adjacent to at least one contact region of the contact structure of a further display element and is electrically conductively connected thereto by a connecting means. In this way, row and/or column conductor tracks of adjacent display elements can be connected to each other so that several display elements form the display area of the video wall.

The connecting means is advantageously arranged in a gap between the display elements and is embodied as solder, adhesive or conductive paste. The solder can be applied as a solder ball on the notched edge side or inserted between vertical edge sides. The adhesive can be an insulating or conductive adhesive, for example an anisotropic conductive paste (ACP) with conductive particles. A silver ink as conductive paste is an example of a connecting means.

In a method for producing a contact structure in a plurality of display elements, a plurality of carriers with circuit structures on the front and rear sides are aligned so that edge side regions of the carriers on which contact structures are to be applied point in a same direction, and the contact structures are applied to the edge side regions. The alignment can be achieved by piling up the carriers into a stack. Spacers can be placed between the carriers. The application of the contact structure can be done by a coating jet, plasma coating, vapor deposition or a planar layer application with subsequent targeted material removal, which offers a large freedom in the choice of suitable processes.

The invention is illustrated in the following by means of the drawing.

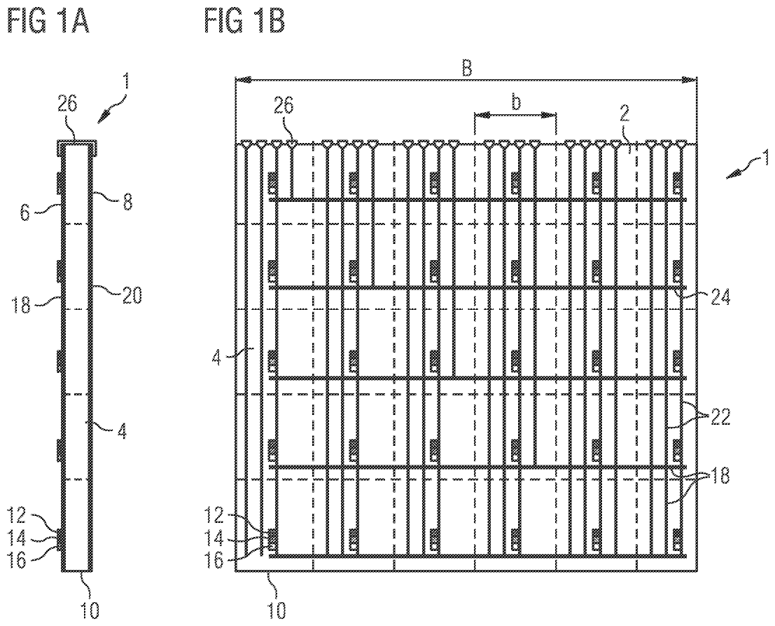

FIGS. 1A and 1B show a top view and a side view of an exemplified embodiment of a display element.

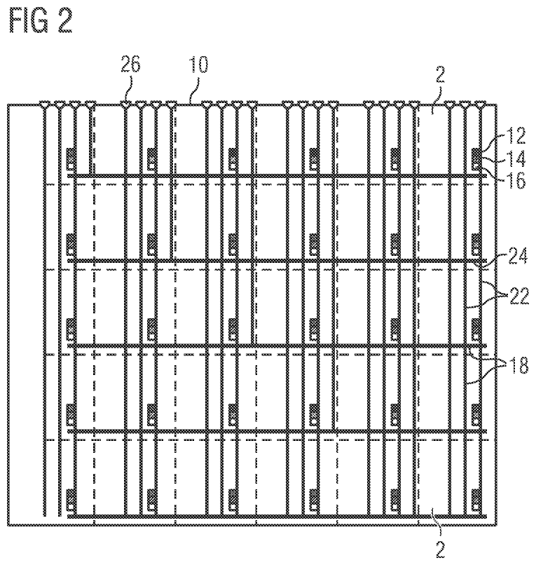

FIG. 2 shows a top view of a further exemplified embodiment of a display element.

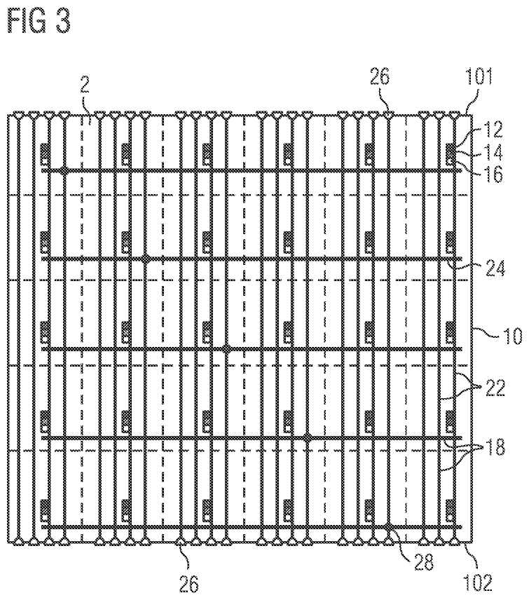

FIG. 3 shows a top view of a further exemplified embodiment of a display element.

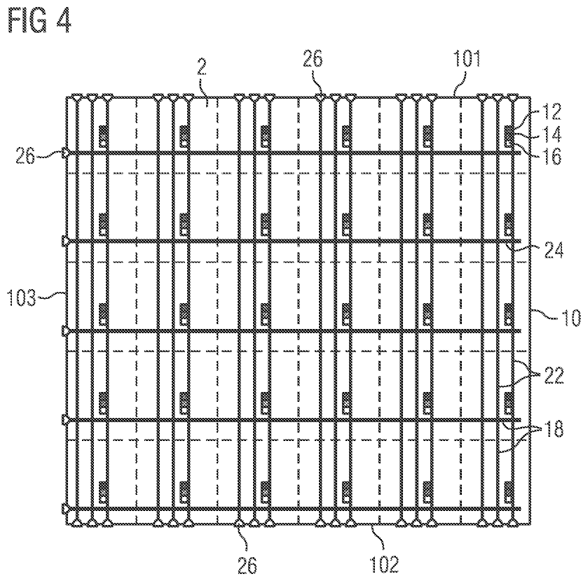

FIG. 4 shows a top view of a further exemplified embodiment of a display element.

FIG. 5 shows a top view of a further exemplified embodiment of a display element.

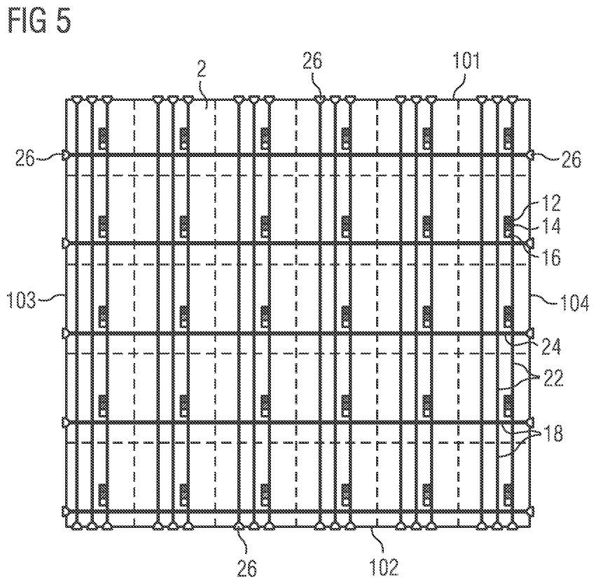

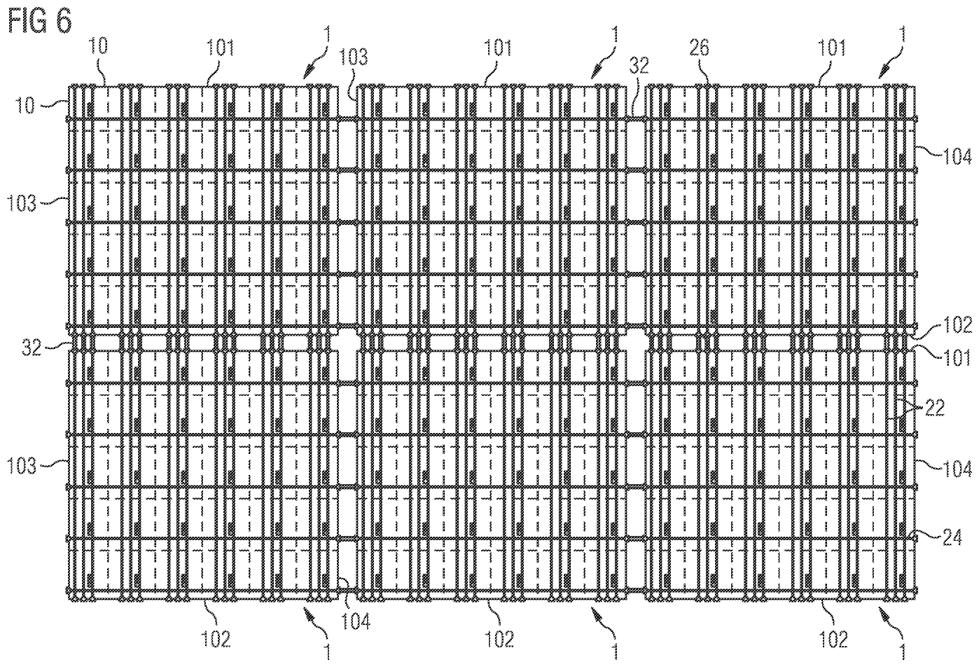

FIG. 6 shows a top view of an exemplified embodiment of a display device.

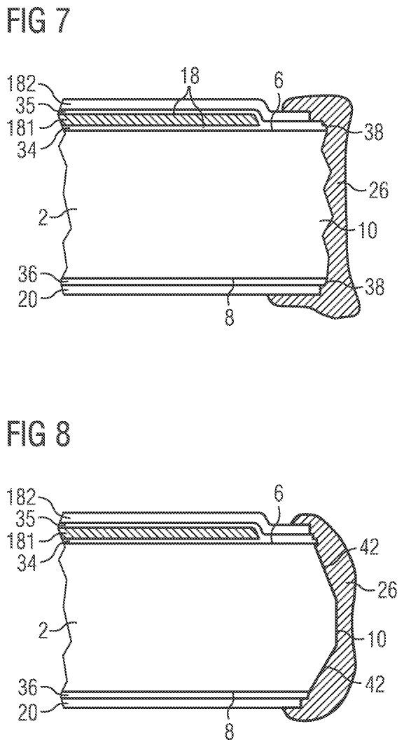

FIG. 7 shows an edge side region of an exemplified embodiment of a display element in a sectional view.

FIG. 8 shows an edge side region of a further exemplified embodiment of a display element in a sectional view.

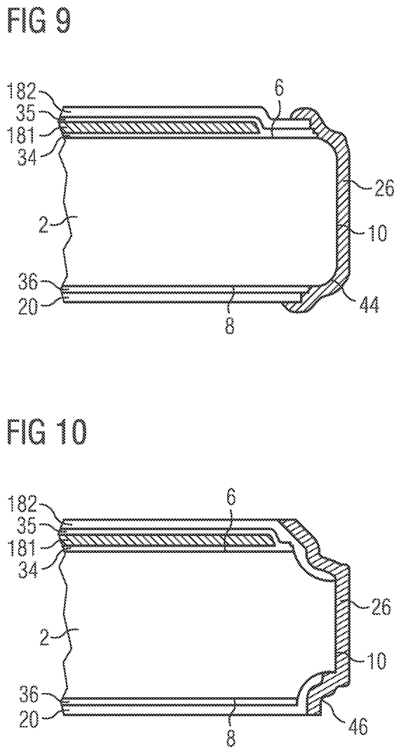

FIG. 9 shows an edge side region of a further exemplified embodiment of a display element in a sectional view.

FIG. 10 shows an edge side region of a further exemplified embodiment of a display element in a sectional view.

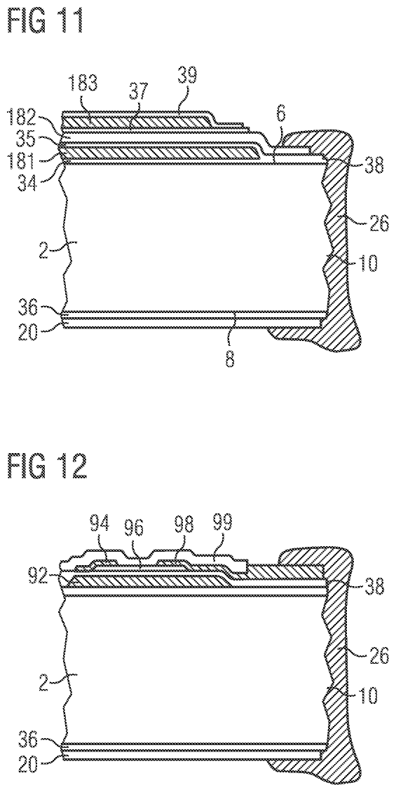

FIG. 11 shows an edge side region of a further exemplified embodiment of a display element in a sectional view.

FIG. 12 shows an edge side region of a further exemplified embodiment of a display element in a sectional view.

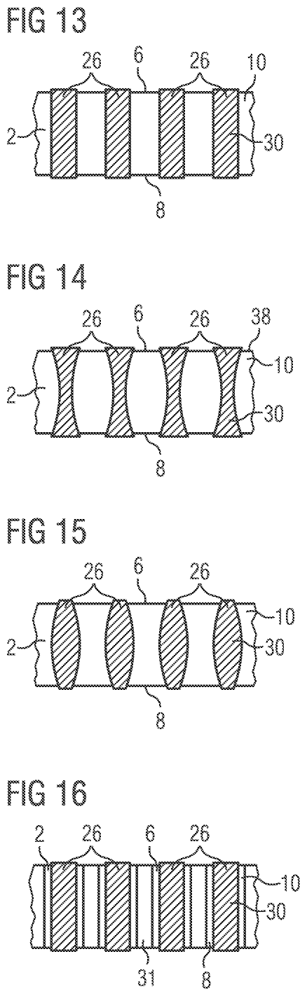

FIG. 13 shows a top view of an edge side of an exemplified embodiment of a display element.

FIG. 14 shows a top view of an edge side of a further exemplified embodiment of a display element.

FIG. 15 shows a top view of an edge side of a further exemplified embodiment of a display element.

FIG. 16 shows a top view of an edge side of a further exemplified embodiment of a display element.

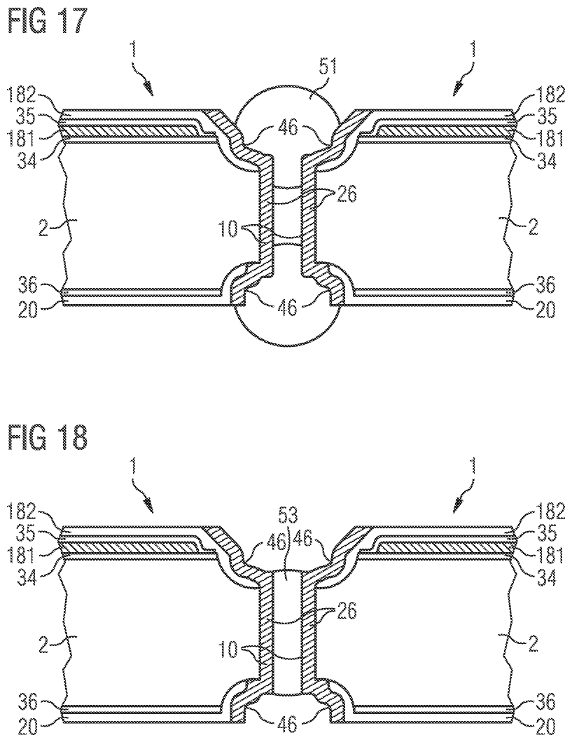

FIG. 17 shows a sectional view of edge side regions of two adjacent display elements of an exemplified embodiment of a display device.

FIG. 18 shows a sectional view of edge side regions of two adjacent display elements of a further exemplified embodiment of a display device.

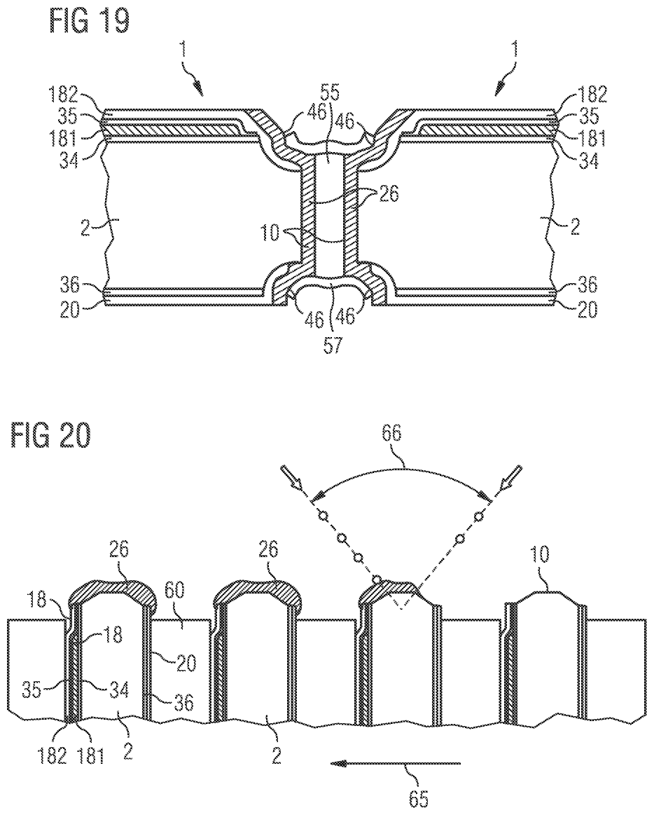

FIG. 19 shows a sectional view of edge side regions of two adjacent display elements of a further exemplified embodiment of a display device.

FIG. 20 illustrates a coating process in the manufacture of a plurality of display elements.

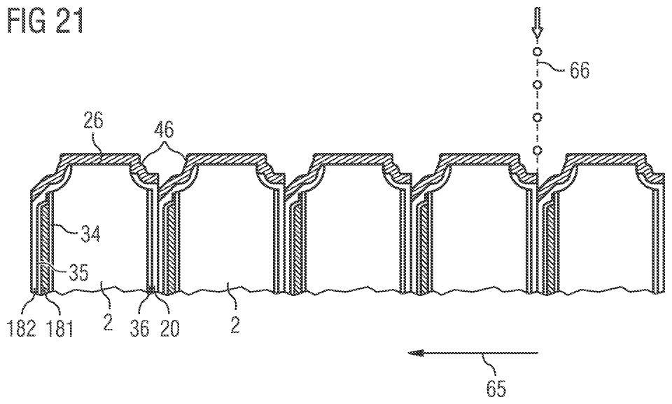

FIG. 21 illustrates an alternative coating process in the manufacture of a plurality of display elements.

FIGS. 1A and 1B show a top and side view, respectively, of an exemplified embodiment of a display element for a video wall, also known as a video wall module.

The display element 1 has an exemplary width B of 100 mm to 1000 mm and comprises a plurality of pixels 2. The height can be greater or smaller, but still of the same order of magnitude. The pixels 2 are arranged in rows and columns, resulting in an m×n arrangement of pixels 2. A pixel 2 has an exemplary width b of 0.5 mm to 5 mm. The height can be the same. The pixels 2 are illustrated by the broken lines in FIG. 1B.

The display element 1 comprises a glass carrier 4, also known as a glass substrate, which has a front side 6, a rear side 8 and an edge side 10, commonly known as a rim or edge. The plate-shaped glass carrier 4 with a rectangular basic shape has a thickness in the range of 0.1 mm to 2 mm.

Glass as a substrate for display elements 1 of a video wall has the following advantages, for example over a printed circuit board (PCB): Glass is hard, inexpensive and transparent. It has a low linear coefficient of thermal expansion (CTE), a high temperature cycle resistance of the contact structure. It enables thin-film metallization with small structural sizes (3 μm) and high structure position accuracy even after temperature stress. Electronics can be integrated, for example as thin-film transistor (TFT).

On the front side 6 of the carrier 4, a plurality of light emitting components are arranged, each in groups of three in a pixel 2 with a red LED chip 12, a green LED chip 14 and a blue LED chip 16. Alternatively, the LEDs emitting in the three colours can be integrated on one chip. The RGB LED chips 12, 14, 16 in each pixel 2 are driven by an active matrix circuit or passive matrix circuit.

Circuit structures in the form of structured metallizations 18, 20 are arranged on the front and rear sides 6, 8 respectively. The metallizations 18, 20, especially on the front side 6, can be embodied in multilayer fashion. In this exemplified embodiment, the circuit structures comprise row and column conductor tracks 24, 22, also known as row and column contacts, by means of which the components 12, 14, 16 can be selectively driven. The row and column conductor tracks 24, 22 can be arranged in different levels. On the front side 6, alternatively or additionally also on the rear side 8, small integrated circuits, so-called micro-ICs or μICs, drivers and/or TFT electronics can be arranged next to the LED chips 12, 14, 16.

The arrangement of the LED chips 12, 14, 16 is divided into pixels 2. Each pixel 2 is connected to its neighbours via the column and row contacts 22, 24 of the metallization 18 on the front side 6. The display element 1 is smaller than an integer multiple of the pixel size in order to still provide space for mounting adjacent display elements 1 and due to mounting tolerances from display element 1 to display element 1 and manufacturing tolerances of the display elements 1. In this exemplified embodiment, the LED chips 12, 14, 16 are arranged centrally in the pixels 2, so that the distance of the LED chip groups to their row neighbours is the same and to their column neighbours is also the same. However, the distance of the LED chip groups in the outer pixels to the upper and lower edges is also the same, as is the distance in the outer pixels to the right and left edges.

Contact structures 26 are arranged on the edge side 10 of display element 1. These are designed as structured metallization of the edge side 10 from the front to the rear side 6, 8 in order to connect electrically conductively with each other the metallizations 18, 20 on the front and rear side 6, 8.

FIG. 2 shows a top view of a further exemplified embodiment of a display element 1. To avoid repetitions, only differences to the exemplified embodiment shown in FIGS. 1A and 1B are described.

In this exemplified embodiment, the groups of LED chips 12, 14, 16 are arranged off-center in the pixels 2. Due to the increased distance of the LED chip groups to the edge side 10 at least on one side, more space is created for the contact structures 26 at the edge. The off-center arrangement can be achieved by a horizontal and/or vertical shift of the LED chips 12, 14, 16 relative to a central arrangement. Both is the case in this exemplified embodiment.

FIG. 3 shows a top view of a further exemplified embodiment of a display element 1. To avoid repetitions, only differences to the exemplified embodiment shown in FIGS. 1A and 1B are described.

The display element 1 comprises contact structures 26 on opposite edge side regions 101, 102, in this figure top and bottom. All column contacts 24 are contacted to one another from top to bottom. Contact to the rear side 8 is made on two opposite edge side regions 101, 102. The row contacts 24 are connected with respectively one additional column contact 22 by means of vias 28 between the metallization planes on the front side 6.

FIG. 4 shows a top view of a further exemplified embodiment of a display element 1. To avoid repetitions, only differences to the exemplified embodiment shown in FIGS. 1A and 1B are described.

The display element 1 comprises a contact structure 26 on three edge side regions 101, 102, 103, in this figure top, bottom and left. Alternatively, a contact can be made on the right instead of the left. It is also conceivable that the contact structure 26 is arranged both on the right and left and at the top or bottom of the edge side regions.

FIG. 5 shows a top view of a further exemplified embodiment of a display element 1. To avoid repetitions, only differences to the exemplified embodiment shown in FIGS. 1A and 1B are described.

The display element 1 comprises a contact structure 26 on all four edge regions 101, 102, 103, 104, in this figure top, bottom, left and right. In this way, not only are all column contacts 22 contacted from top to bottom, but also the row contacts 24 from left to right.

The exemplified embodiments shown in FIGS. 4 and 5 illustrate that row contacts 24 on one edge side region 103, 104 (right or left) or on two opposite edge side regions 103, 104 (left and right) can be contacted to the rear side 8. The advantage of this arrangement is that a simple display element to display element wiring in the sense of a cross-matrix wiring, in which the display elements 1 are arranged in rows and columns, is possible across many display elements 1 by connecting to each other the contact structures 26 on the edge sides 10 of adjacent display elements 1.

The advantage of a contact structure 26 on only one edge side region 101, 102, 103, 104, as shown in FIGS. 1A and 1B, is that the coating effort is many times lower if only one instead of all four edge side regions 101, 102, 103, 104 is coated with a metallization.

FIG. 6 shows an exemplified embodiment of a display device with a plurality of display elements 1 as described in FIG. 5, i.e. with the contact structure 26 on all four edge side regions 101, 102, 103, 104. The display elements 1 are arranged in a lateral plane so that left and right edge side regions 103, 104 of two adjacent display elements 1 are adjacent in a row and upper and lower edge side regions 101, 102 of two adjacent display elements 1 are adjacent in a column. Connecting means 32 are provided between contact structures 26 of two adjacent edge side regions 101, 102, 103, 104, which connecting means 32 establish an electrically conductive connection between the contact structures 26. In this way, row contacts 22 are connected to each other across several display elements 1, as are column contacts 24.

The display elements 1 are arranged in the display device in such a way that the pixel pitch remains equidistant. The space between the display elements 1 is used for wiring the display elements 1 so that the connecting means 32 are arranged in the gap between the edge sides 10.

Alternatively, a rear connection of the display elements 1 can be made, in which a plug-in element is arranged on the rear side 8 of each display element 1 to form the connection from display element 1 to display element 1. The plug-in element can be soldered on, for example, via the rear side metallization 20.

FIG. 7 shows an edge side region of an exemplified embodiment of a display element 1 in a sectional view. The exemplified embodiment comprises a multi-layer front side metallization 18. The glass substrate of the carrier 2 comprises a first front side passivation 34 and a rear side passivation 36 on its front and rear sides 6, 8. The structured rear side metallization 20 is applied to the latter. On the front side 6, a first metallization 181 and a second metallization 182 with a second front side passivation 35 in between is arranged on the first front side passivation 34. Regions of the second metallization 182 run almost to edge 38 where the front side 6 and the edge side 10 meet.

The edge side 10 may, for example, have been formed by scoring and breaking the carrier material. The contact structure 26 comprises metallized contact regions extending from an edge region on the front side 6 over the edge side 10 to an edge region on the rear side 8, so that an electrically conductive connection is formed between the metallizations 18, 20 on the front and rear sides 6, 8.

The first and second metallization 181, 182 on the front side 6 are isolated from each other by the second passivation 35. One of the metallizations 181, 182, in this case the second, comprises regions in the edge region of the front side 6 which are not covered by the passivation. However, it is partially covered by the metallization of the contact structure 26, as well as the metallization 20 for the electrical contact on the rear side 8.

In this case, the metallization of the contact structure 26 is thicker on the edges 38 than in the other regions. This is advantageous because increased mechanical stress can occur there.

FIG. 8 shows an edge side region of a further exemplified embodiment of a display element in a sectional view. In order to avoid repetitions, the description focuses on the differences to the exemplified embodiment described in FIG. 7.

As an alternative to the edge side 10 being simply scored and broken as described above, the edge side 10 can also be chamfered, for example at an angle of 30°, 45° or 60°. For example, the chamfer 42 can extend over 10%, 20% or 40% of the carrier thickness. The edge side 10 in FIG. 8 comprises chamfers 42, i.e. a bevelled edge, at the transition to front and rear side 6, 8. The metallization of the contact structure 26 on the chamfers 42 is thicker than in the other regions. This is advantageous because increased mechanical stress can occur there.

FIG. 9 shows an edge side region of a further exemplified embodiment of a display element 1 in a sectional view. To avoid repetitions, the description focuses on the differences to the exemplified embodiment described in FIG. 7.

The transition from the edge side 10 to front and rear sides 6, 8 is rounded. Due to rounding 44, the edge side 10 has a convex profile. The metal thickness of the contact structure 26 is essentially the same or homogeneous.

Roundings 44 and chamfers 42 reduce the risk of damage to the metallization of the contact structure 26 and the carrier glass.

FIG. 10 shows an edge side region of an exemplified embodiment of a display element 1 in a sectional view. To avoid repetitions, the description focuses on the differences to the execution example described in FIG. 7.

The transition from the edge side 10 to front and back side 6, 8 is notched. The notch 46 is a concave profile incision at the top and bottom of the edge side 10. In this exemplified embodiment, the metallizations 182, 20 on the front and rear sides 6, 8 extend into the notched transition to the edge side 10. The contact structure 26 extends from the upper notched area of the edge side 10 to the lower notched area. In this exemplified embodiment, it does not have a metal coating on the top and bottom, but only a side metal coating on the edge side 10.

Notching before separation and of the front and rear side metallization facilitates edge metallization because it only needs to be done on the edge side 10 and not on the front and rear side.

FIG. 11 shows an edge side region of an exemplified embodiment of a display element 1 in a sectional view. To avoid repetitions, the description focuses on the differences to the exemplified embodiment described in FIG. 7.

This exemplified embodiment shows a purely passive glass substrate as carrier 2 with several metallization layers 181, 182, 183 and passivation layers 34, 35, 37, 39, namely three metallization layers 181, 182, 183, on, under and between which four passivation layers 34, 35, 37, 39 are arranged. The placement of active components (e.g. by μlCs) is then carried out after the layers have been applied.

It is not necessary that the top metal layer is led to the edge metallization of the contact structure 26; in this case it is the middle metallization 182. Different metal layers can also be led to the edge 38. These can then be connected to each other by the contact structure 26.

FIG. 12 shows an edge side region of an exemplified embodiment of a display element 1 in a sectional view, which illustrates that the use of TFT panels with amorphous silicon, polysilicon or oxide semiconductors (IGZO) is also conceivable. To avoid repetitions, the description focuses on the differences to the exemplified embodiment described in FIG. 7.

A gate metal structure 92 of metal oxide is arranged on the front side 6. Thereon, a passivation layer 94 of silicon nitride SiNₓ is arranged, where a semiconductor material 96, e.g. indium-gallium-zinc oxide (IGZO), is arranged. On the semiconductor material 96, drain and source metal structures 98 of metal oxide are arranged, which extend on the passivation layer 94 to edge 38 and are connected to the contact structure 26. A passivation layer 99 is arranged on the drain and source metal structures 98.

FIG. 13 shows a top view of an edge side 10 of an exemplified embodiment of a display element 1. The contact structure 26 comprises a plurality of conductive contact regions 30 with lateral edges from the front side to the rear side 6, 8. The edges of the metallizations embodied as conductive contact regions 30 are parallel to each other in this exemplified embodiment.

FIG. 14 shows a top view of an edge side 10 of a further exemplified embodiment of a display element 1. To avoid repetitions, the description concentrates only on the differences to the exemplified embodiment shown in FIG. 13.

In this exemplified embodiment, the edges of the metallic contact regions 30 are concave to each other. The concave structure has the advantage that the sensitive edge 38 is associated with a low risk of failure because the metallization is broader at the edge 38.

FIG. 15 shows a top view of an edge side 10 of a further exemplified embodiment of a display element 1. To avoid repetitions, the description concentrates only on the differences to the exemplified embodiment shown in FIG. 13. In this exemplified embodiment, the edges of the metallic contact region 30 are convex to each other.

FIG. 16 shows a top view of an edge side 10 of a further exemplified embodiment of a display element 1. To avoid repetitions, the description focuses only on the differences to the exemplified embodiment shown in FIG. 13.

In this exemplified embodiment, strip-shaped insulating regions 31 are provided between the metallic contact regions 30. The insulating region 31, e.g. made of insulating lacquer or solder resist lacquer, which serves as an insulating web, avoids short circuits in a display element-to-display element connection. If no display element-to-display element connection is provided, e.g. due to the provision of connecting means (e.g. plugs) on the rear side 8 of the display elements 1, the insulating region 31 is not required.

FIG. 17 shows a sectional view of edge side regions of two adjacent display elements 1 of an exemplified embodiment of a display device. The display elements 1 comprise a notched edge side 10. A display element-to-display element connection can be made by a solder ball 51 which is placed on or shot on.

The display elements 1 are connected by two connecting means, which are embodied as solder balls 51 arranged in the upper and lower notches 46. Together, the notches 46 of the two display elements 1 form a trench-shaped profile that allows targeted insertion of the solder balls 51 and a secure connection of the contact structures 26. It is also conceivable that the solder ball 51 is only inserted into the front side notches 46 or the rear side notches 46.

FIG. 18 shows a sectional view of edge side regions of two adjacent display elements 11 of a further exemplified embodiment of a display device. To avoid repetitions, the description focuses only on differences to the exemplified embodiment shown in FIG. 17.

In this exemplified embodiment, the connecting means is a solder ball or a conductive adhesive 53, which has been inserted between the regions of the edge side 10 perpendicular to the front and rear side 10, so that an electrical conductor of solder or adhesive, e.g. conductive adhesive, is located in the middle.

FIG. 19 shows a sectional view of edge side regions of two adjacent display elements 1 of a further exemplified embodiment of a display device. To avoid repetitions, the description focuses only on differences to the exemplified embodiment shown in FIG. 17.

The gap between the display elements 1 is filled with an insulating adhesive 55, which has been inserted between the regions of the edge sides 10 perpendicular to the front and rear sides 6, 8. The electrical connection from display element 1 to display element 1 is made by a conductive paste 57, e.g. printed silver ink, which runs from the contact structure 26 in the notch 46 of one display element 1 via the adhesive 55 to contact structure 26 in the notch 46 of the other display element 1.

FIG. 20 illustrates a coating process in the production of a plurality of display elements 1.

After scoring and breaking and, in this exemplified embodiment, chamfering, the carriers 2 with the metallizations 181, 182, 20 are stacked one on top of the other. The carriers 2 may already have been separated to the size of the later display element 1 or they may still be in the assembly as carrier strips or bars, if not yet completely separated in all directions. To coat the glass side surfaces, the carriers 2 are stacked one on top of the other after separation so that at least one edge side 10 is freely accessible.

The carriers 2 are aligned so that the edge side regions of the carriers 2 on which contact structures 26 are to be applied point in a same direction. Spacers 60 are arranged between the carriers 2. The spacers 60 can be plate-shaped, e.g. made of glass or PTFE, and can each be arranged between the front and rear sides 6, 8 of adjacent carriers 2. The edge sides 10 of the carriers 2 to be coated protrude beyond the spacers 60. The spacer 60 allows the edge side regions 10 to be coated to be accessible for coating.

The contact structures 26 are applied by means of coating jets 66, in this exemplified embodiment two coating jets 66, which are directed at an angle to the edge side regions 10 to be coated and apply the contact structure 26. The coating can be made with one or more coating jets 66, which can be inclined to each other. In this case, a material is applied from above at an angle using the coating jet 66, e.g. of silver ink, to cover the left edge side 10 and the adjacent front side metallization 18. The second coating jet 66 covers the right edge side 10 and the adjacent rear side metallization 20. During the coating process, the stack of carriers 2 and spacers 60 is moved in one direction so that the edge side region 10 of one carrier 2 is coated after the other. The feed is illustrated by the arrow 65.

FIG. 21 illustrates a further exemplary coating process in the production of a plurality of display elements. To avoid repetitions, only the differences to the previous coating process in FIG. 20 are described.

In this exemplified embodiment with edge notch 46 of the carriers 2, the carriers 2 can be stacked directly to each other and a vertical bombardment from above is carried out for metallization. The metallization is made in a structured way.

Possible alternative coating processes are: Silver ink deposition, also known as “jetting”, copper plasma coating, mask evaporation, sputtering as PVD process (abbreviation of “Physical Vapor Deposition”) with lithography and etching or lithography and vapor deposition as PVD process and lift-off or PVD process and laser ablation if necessary with electroplating (e-less). Wet chemical processes have the disadvantage that they can lead to residues in the gaps between the carriers 2.

The features of the exemplified embodiments can be combined. The scope of protection of the invention is not limited to the examples given hereinabove. The invention is embodied in each novel characteristic and each combination of characteristics, which particularly includes every combination of any features which are stated in the claims, even if this feature or this combination of features is not explicitly stated in the claims or in the examples.

### LIST OF REFERENCE SIGNS

1 display element

2 pixel

4 carrier

6 front side

8 rear side

10 edge side

12, 14, 16 LED chip

18, 20, 181, 182, 183 metallization

22, 24 conductor track

26 contact structure

30 contact region

31 insulating regions

32 connecting means

34, 35, 36, 37, 39, 94, 99 passivation

38 edge

42 chamfer

44 rounding

46 notch

51 solder ball

53, 55 adhesive

57 conductive paste

60 spacer

65 arrow

66 jet

92 gate metal structure

96 semiconductor material

98 drain and source metal structures

101, 102, 103, 104 edge side regions

B, b width

1. A display element for a video wall having a plurality of light-emitting components on a carrier which has a front side, a rear side and an edge side running between the front and rear sides, wherein circuit structures are arranged on the front side and the rear side and are electrically conductively connected to one another via a contact structure arranged on the edge side, and wherein the edge side is embodied in a scored, broken, ground, polished, melted, sawn, chamfered, rounded or notched way.

2. The display element according to claim 1,
wherein the contact structure comprises a plurality of electrically conductive contact regions, which each connect a region of the circuit structure on the front side extending to the edge side with a region of the circuit structure on the rear side extending to the edge side.

3. The display element according to claim 1 or 2,
wherein the contact region comprises edges running from the front to the rear side, which edges are parallel, concave or convex to one another.

4. The display element according to claim 2,
wherein a region of electrically insulating material is arranged on the edge side between two adjacent contact regions.

5. The display element according to claim 1,
wherein the carrier has a rectangular basic shape with opposite first edge side regions and opposite second edge side regions running perpendicularly to the first edge side regions, and the contact structure
is arranged on only one of the first and second edge side regions,
or is arranged on only one of the first edge side regions and on only one of the second edge side regions,
or is arranged only on either the first edge side regions or only on the second edge side regions,
or is arranged on three of the first and second edge side regions,
or is arranged on both the first and second edge side regions.

6. The display element according to claim 1,
comprising a plurality of pixels arranged in rows and columns, wherein one or more chips emitting red, green and blue light are arranged in each pixel.

7. The display element according to claim 1,
wherein the circuit structures comprise row and column conductor tracks and a drive circuit or parts of a drive circuit for selectively driving the components.

8. The display element according to claim 1,
wherein the circuit structure comprises on the front side and/or on the rear side a plurality of conductive structure layers arranged one above the other, at least one of which is connected to the contact structure.

9. (canceled)

10. A display device with a plurality of display elements according to claim 1, arranged in such a way that at least one contact region of the contact structure of a display element is adjacent to at least one contact region of the contact structure of a further display element and is electrically conductively connected thereto by a connecting means.

11. The display device according to claim 10,
wherein the connecting means is arranged in a gap between the display elements and is embodied as solder, adhesive or conductive paste.

12. A method for producing a contact structure in a plurality of display elements, the method comprising:
aligning a plurality of carriers with circuit structures on front and rear sides so that edge side regions of the carriers on which the contact structures are to be applied point in a same direction; and
applying the contact structures.

13. The method according to claim 12,
wherein spacers are placed between the carriers.

14. The method according to claim 12,
wherein the application is carried out by a coating jet, by plasma coating, by vapour deposition or by a planar layer application with subsequent targeted material removal.
